(19) United States
(12) Patent Application Publication
(10) Pub. No.: US 2026/0081116 A1
(43) Pub. Date: Mar. 19, 2026

(54) TEMPERATURE CONTROL SYSTEM AND METHOD OF CONTROLLING TEMPERATURE CONTROL SYSTEM

(71) Applicant: Tokyo Electron Limited, Tokyo (JP)

(72) Inventors: Masahiko YOKOI, Miyagi (JP); Ryutaro SUDA, Miyagi (JP); Takeshi KATAHIRA, Miyagi (JP); Maju TOMURA, Miyagi (JP); Yoshihide KIHARA, Miyagi (JP)

(73) Assignee: Tokyo Electron Limited, Tokyo (JP)

(21) Appl. No.: 19/394,948

(22) Filed: Nov. 20, 2025

Related U.S. Application Data
(63) Continuation of application No. PCT/JP2025/004837, filed on Feb. 13, 2025.

(30) Foreign Application Priority Data
Feb. 22, 2024 (JP) 2024-025318

(51) Int. Cl. H01J 37/32

(52) U.S. Cl. CPC H01J 37/32522; H01J 2237/002

(57) ABSTRACT

A temperature control system for cooling structures in a plasma processing chamber, the temperature control system includes a tank that stores a gaseous temperature control medium at normal temperature and pressure; a cooler that liquefies the temperature control medium in the tank; an outflow flow path connected to an outflow port of the tank and forming a flow path through which the temperature control medium flows out to a temperature control structure that cools the structures by heat exchange with the temperature control medium; an inflow flow path connected to an inflow port of the tank and forming a flow path through which the temperature control medium flows in from the temperature control structure after heat exchange; a pump in the outflow flow path and that moves the temperature control medium stored in the tank; and a pressing structure that presses the liquid temperature control medium stored in the tank.

### CROSS-REFERENCE TO RELATED APPLICATIONS

This application is a continuation application of International Application PCT/JP2025/004837, filed on Feb. 13, 2025, and designating the U.S., and claims priority to Japanese Application No. 2024-025318, filed on Feb. 22, 2024, the entire contents of each of which are incorporated herein by reference.

### FIELD

The present disclosure relates to a temperature control system and a method of controlling the temperature control system.

### BACKGROUND

A temperature control medium processing device disclosed in Patent Literature 1 is a temperature control medium processing device that recovers or replenishes a temperature control medium for a module using the temperature control medium, and includes a tank that stores the temperature control medium, a first inflow flow path that is connected to a first inflow port of the tank and into which the temperature control medium flows, an inflow connection portion that connects the first inflow flow path and a flow path from the module, an outflow flow path that is connected to an outflow port of the tank and from which the temperature control medium flows out, an outflow connection portion that connects the outflow flow path and a flow path to the module, and a pump that is provided on the outflow flow path and sends the temperature control medium stored in the tank.

Patent Literature 1: JP 2021-136372 A

### SUMMARY

According to an aspect of a present disclosure, there is provided a temperature control system for cooling structures in a plasma processing chamber, the temperature control system including a tank that stores a gaseous temperature control medium at normal temperature and normal pressure; a cooler that liquefies the temperature control medium stored in the tank; an outflow flow path connected to an outflow port of the tank, the outflow flow path forming a flow path through which the temperature control medium flows out to a temperature control structure that cools the structures by heat exchange with the temperature control medium; an inflow flow path connected to an inflow port of the tank and forming a flow path through which the temperature control medium flows in from the temperature control structure after heat exchange; a pump in the outflow flow path and that moves the temperature control medium stored in the tank; and a pressing structure that presses the liquid temperature control medium stored in the tank.

### BRIEF DESCRIPTION OF DRAWINGS

FIG. 1 is a diagram illustrating an example of a temperature control system according to an embodiment of the present disclosure.

FIG. 2 is a diagram illustrating an example of a state in which a temperature control medium is stored in a tank.

FIG. 3 is a diagram illustrating an example of a state during operation of a temperature control system.

FIG. 4 is a diagram illustrating an example of a state in which a temperature control medium in a pipe on the side of a temperature control unit is exhausted.

FIG. 5 is a graph indicating an example of P-H characteristics of the temperature control medium.

FIG. 6 is a graph indicating an example of change in a flow rate due to pressing of the temperature control medium.

FIG. 7 is a flowchart illustrating an example of a method of controlling the temperature control system at the time of storage and circulation in the present embodiment.

FIG. 8 is a flowchart illustrating an example of a method of controlling the temperature control system at the time of exhaust in the present embodiment.

### DESCRIPTION OF EMBODIMENT

The present disclosure provides a temperature control system and a method of controlling the temperature control system that can be used in a low temperature region.

Hereinafter, embodiments of a disclosed temperature control system and method of controlling the temperature control system will be described in detail with reference to the drawings. Note that the disclosed technology is not limited by the following embodiments.

In a comparative chiller, a temperature control medium having low volatility at normal temperature and normal pressure is used. Such a temperature control medium may be harmless to the environment, and an operation that allows release of the temperature control medium to the atmosphere has been performed. However, in recent years, environmental pollution due to PFAS (perfluoroalkyl and polyfluoroalkyl compounds) has been pointed out, and the configuration and operation of the temperature control medium and the chiller are reviewed. Therefore, by supplying the temperature control medium in an airtight state, it is expected to suppress release of the temperature control medium to the atmosphere and to expand a usable temperature range of the temperature control medium. That is, the temperature control system is expected to be used in a low temperature region.

### Configuration of Temperature Control System

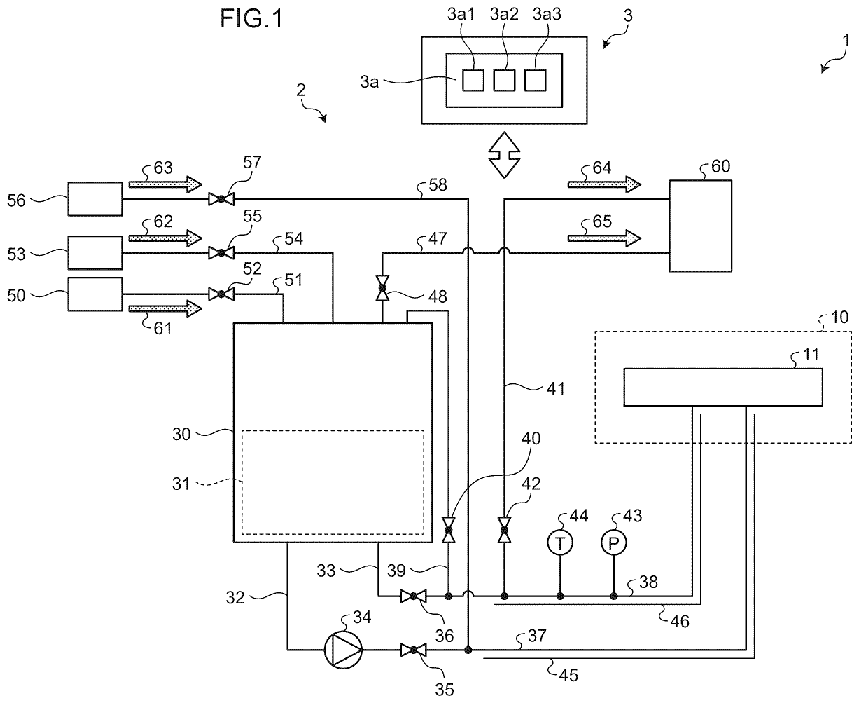

FIG. 1 is a diagram illustrating an example of a temperature control system according to an embodiment of the present disclosure. As illustrated in FIG. 1, the temperature control system 1 includes a chiller unit (e.g., chiller) 2 and a control unit (e.g., controller) 3. The chiller unit 2 includes a tank 30, a cooling mechanism (e.g., cooler) 31 in the tank 30, a pump 34, a supply mechanism (e.g., supply) 50, a pressing mechanism (e.g., pressing structure) 53, a purge mechanism (e.g., purge structure) 56, and a detoxification mechanism (e.g., detoxification structure) 60. In an implementation, the temperature control system 1 is a temperature control system 1 that cools members or structures in a plasma processing chamber 10, and includes the tank 30, the cooling mechanism 31, an outflow flow path (pipes 32 and 37), an inflow flow path (pipes 33 and 38), and the pump 34. In an implementation, the temperature control system 1 may be included in a plasma processing apparatus including the plasma processing chamber 10.

In the tank 30, the cooling mechanism 31 liquefies and stores a gaseous temperature control medium (supplied from the supply mechanism 50 through a pipe 51 and a valve 52) at normal temperature and normal pressure (e.g., 20° C. and 1 atm). In an implementation, the tank 30 stores a gaseous temperature control medium at normal temperature and normal pressure. The tank 30 is, for example, a reservoir tank in an airtight state. In the tank 30, the pipe 32 (which is an outflow flow path) is connected to an outflow port, and the pipe 33 (which is an inflow flow path) is connected to an inflow port.

The pipe 32 is connected to a pipe (e.g., purge pipe) 58, and is connected to a temperature control unit (e.g., temperature control structure) 11 in the plasma processing chamber 10 as the pipe 37. In an implementation, the pipes 32 and 37, as an example of the outflow flow path, are connected to the outflow port of the tank 30 and are configured such that the temperature control medium flows out to the temperature control unit 11 that cools the members by heat exchange by the temperature control medium. Note that the temperature control unit 11 is provided, for example, in a member to which a thermal load is applied, such as a substrate support or an upper electrode, and the member is cooled by heat exchange when the temperature control medium flows through an internal flow path. The pipe 32 is provided with a pump 34 and a valve 35. The pipe 58 is connected to the purge mechanism 56 via a valve 57. The pipe 33 is connected to pipes 39 and 41, and is connected to the temperature control unit 11 in the plasma processing chamber 10 as or through the pipe 38. In an implementation, the pipes 33 and 38, as an example of the inflow flow path, are connected to the inflow port of the tank 30, and are configured such that the temperature control medium, after heat exchange, flows in from the temperature control unit 11. The pipe 33 is provided with a valve 36. The pipe 38 is provided with a pressure gauge 43 and/or a thermometer 44. The pipe (e.g., gaseous return pipe) 39 is connected to an upper portion of the tank 30 via a valve (e.g., gaseous return valve) 40. The pipe 41 is connected to the detoxification mechanism 60 via a valve 42. In an implementation, the temperature control medium flowing out of the tank 30 is circulated through the paths of the pipes 32 and 37, the temperature control unit 11, and the pipes 38 and 33. In an implementation, the pipes 32 and 37 are an example of an outflow flow path, and the pipes 33 and 38 are an example of an inflow flow path. The pipe 41 is an example of an exhaust flow path. In an implementation, the exhaust flow path (pipe 41) is connected to the tank 30 and the inflow flow path (pipes 32 and 37), and exhausts the temperature control medium. The valve 35 is an example of a first valve, and the valve 36 is an example of a second valve.

The cooling mechanism 31 is controlled to liquefy the gaseous temperature control medium supplied into the tank 30 at normal temperature and normal pressure. In an implementation, the cooling mechanism 31 is configured to liquefy the temperature control medium stored in the tank 30. In the cooling mechanism 31, for example, the temperature control medium is liquefied by being cooled to a predetermined temperature equal to or lower than the boiling point by a heat exchanger or the like. The cooling mechanism 31 may further cool the temperature control medium using a refrigerant such as liquid nitrogen or liquid helium in the heat exchanger, for example. The predetermined temperature can be, for example, a temperature in a range of +20° C. to −120° C. In an implementation, the cooling mechanism 31 may be provided, for example, in the pipe 33 separately from the tank 30. In an implementation, the cooling mechanism 31 is provided in the tank 30 or in the inflow flow path (pipe 33). In an implementation, the cooling mechanism 31 may be a cooling mechanism of another suitable type as long as it can cool the temperature control medium to a predetermined temperature.

The pump 34 is provided in the pipe 32 of the tank 30 and sends or pumps the liquefied temperature control medium stored in the tank 30 to the temperature control unit 11 in the plasma processing chamber 10 to circulate. In an implementation, the pump 34 is provided in the outflow flow path and sends the temperature control medium stored in the tank 30.

The pressure gauge 43 is a sensor that measures the pressure in the pipe 38. The thermometer 44 is a sensor that measures the temperature in the pipe 38. In an implementation, at least one of the pressure gauge 43 and the thermometer 44 is provided in the inflow flow path (pipe 38). Measurement results of the pressure gauge 43 and the thermometer 44 are output to the control unit 3. The gas-liquid state of the temperature control medium in the pipe 38 can be ascertained from the measurement results of the pressure gauge 43 and the thermometer 44. For example, the pressure gauge 43 and the thermometer 44 can be used to detect that the temperature control medium is exhausted from the pipe 38.

Heaters 45 and/or 46 are provided in or on the pipes 37 and 38, respectively. In an implementation, heaters (heaters 45 and 46) are provided in at least one of the outflow flow path (pipe 37) and the inflow flow path (pipe 38). The heaters 45 and 46 heat the pipes 37 and 38 to vaporize the temperature control medium at the time of purging the inside of the pipes 37 and 38 and the temperature control unit 11. In an implementation, any one of the heaters 45 and 46 may be provided. In an implementation, the outputs of the heaters 45 and 46 may be controlled on the basis of the measurement results of the pressure gauge 43 and the thermometer 44.

The supply mechanism 50 is connected to the tank 30 via the pipe 51 and the valve 52 and is controlled to supply a gaseous temperature control medium. As indicated by an arrow 61, the supply mechanism 50 supplies, for example, gases such as C₃F₈ and C₃H₂F₄ to the tank 30 as temperature control media. In an implementation, the supply mechanism 50 is connected to the tank 30 and supplies a gaseous temperature control medium. The temperature control medium contains at least one of C₃F₈ and C₃H₂F₄. The supply mechanism 50 may be a connection part to factory equipment (application force) in which the temperature control system 1 is installed. In this case, controlling the opening and closing of the valve 52 by the control unit 3 corresponds to controlling the supply mechanism 50.

The pressing mechanism 53 is connected to the tank 30 via the pipe 54 and the valve 55 and is controlled to supply pressing gas. As indicated by an arrow 62, the pressing mechanism 53 supplies, for example, nitrogen gas (for example, N₂ gas) to the tank 30 as a pressing gas. The pressing gas may be another suitable gas as long as the gas has a boiling point lower than that of the temperature control medium and does not react with the temperature control medium. The pressing mechanism 53 supplies a pressing gas into the tank 30 to press the liquid temperature control medium. In an implementation, the pressing mechanism 53 presses the liquid temperature control medium stored in the tank 30. In an implementation, the pressing mechanism 53 supplies a pressing gas into the tank 30 to press the temperature control medium. In an implementation, the pressing gas is a gas having a boiling point lower than that of the temperature control medium. In an implementation, the pressing mechanism 53 may press the liquid temperature control medium by, for example, a mechanical component such as a piston. In an implementation, the pressing mechanism 53 may press the temperature control medium by the piston. In an implementation, the pressing mechanism 53 may press the temperature control medium to pressure that is equal to a vapor pressure of the temperature control medium or higher. The pressing mechanism 53 may be a connection part to factory equipment (application force) in which the temperature control system 1 is installed. In this case, controlling the opening and closing of the valve 55 by the control unit 3 corresponds to controlling the pressing mechanism 53.

The purge mechanism 56 is connected to the pipe 37 via the pipe 58 and the valve 57 and is controlled to supply a gas for purging (which may also be simply referred to as a purge gas hereinafter) into the temperature control unit 11. As indicated by an arrow 63, the purge mechanism 56 supplies, for example, nitrogen gas as a purge gas into the temperature control unit 11 via the pipe 37. That is, the purge mechanism 56 is connected to the outflow flow path (pipe 37) and is able to supply the purge gas into the temperature control unit 11. The purge gas supplied into the temperature control unit 11 is exhausted to the detoxification mechanism 60 via the pipes 38 and 41. The purge mechanism 56 may be a connection part to factory equipment (application force) in which the temperature control system 1 is installed. In this case, controlling the opening and closing of the valve 57 by the control unit 3 corresponds to controlling the purge mechanism 56.

The detoxification mechanism 60 is controlled to detoxify the temperature control medium to be exhausted using, for example, plasma detoxification or the like. The pipe 38 is connected to the detoxification mechanism 60 via the pipe 41 and the valve 42, and the tank 30 is connected thereto via a pipe 47 and a valve 48. The detoxification mechanism 60 includes, for example, a vacuum pump, and is controlled to perform purging of the inside of the temperature control unit 11 or the tank 30 and the inside of each pipe along with the purge mechanism 56 by vacuuming the pipes 41 and 47 as indicated by arrows 64 and 65. That is, the detoxification mechanism 60 is controlled to perform a detoxification process between the temperature control medium purged from the inside of the pipes 37 and 38 and the temperature control unit 11 by the purge mechanism 56 and the temperature control medium purged from the inside of the tank 30 at the time of maintenance or the like of the tank 30. The purge in the tank 30 can use, for example, a pressing gas of the pressing mechanism 53. In addition, the detoxification mechanism 60 may be a connection part to factory equipment (utility) in which the temperature control system 1 is installed. In this case, controlling the opening and closing of the valves 42 and 48 by the control unit 3 corresponds to controlling the detoxification mechanism 60.

The control unit 3 processes computer-executable instructions that cause the chiller unit 2 to execute various processes described in the present disclosure. The control unit 3 may be configured to control each element of the chiller unit 2 to execute various processes described herein. In one embodiment, a part or all of the control unit 3 may be included in the chiller unit 2. The control unit 3 may include a processing unit 3a1, a storage unit 3a2, and a communication interface 3a3. The control unit 3 is realized by, for example, a computer 3a. The processing unit 3a1 can be configured to perform various control operations by reading a program from the storage unit 3a2 and executing the read program. This program may be stored in the storage unit 3a2 in advance, or may be acquired via a medium when necessary. The acquired program is stored in the storage unit 3a2, and is read from the storage unit 3a2 and executed by the processing unit 3a1. The medium may be various storage media readable by the computer 3a, or may be a communication line connected to the communication interface 3a3. The processing unit 3a1 may be a central processing unit (CPU). The storage unit 3a2 may include a random access memory (RAM), a read only memory (ROM), a hard disk drive (HDD), a solid state drive (SSD), or a combination thereof. The communication interface 3a3 may communicate with the chiller unit 2 via a communication line such as a local area network (LAN).

### Operation of Temperature Control System

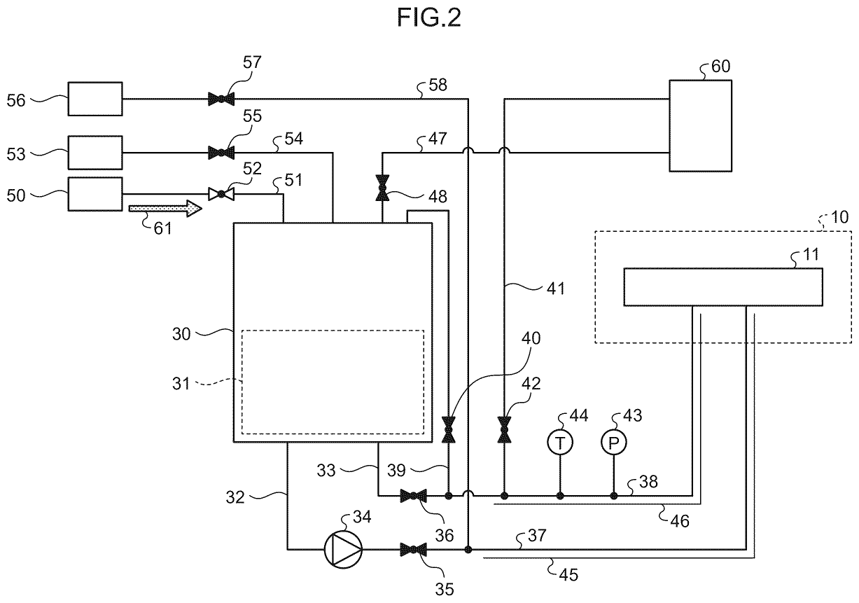

Next, the operation of the temperature control system 1 will be described with reference to FIG. 2 to FIG. 4. In FIG. 2 to FIG. 4, a valve in an open state is indicated in white, and a valve in a closed state is indicated in black. FIG. 2 is a diagram illustrating an example of a state in which a temperature control medium is stored in a tank. As illustrated in FIG. 2, when the temperature control medium is stored in the tank 30, the valves 35, 36, 40, 42, 48, 55, and 57 are controlled to be closed and the valve 52 is controlled to be open. As indicated by an arrow 61, the supply mechanism 50 is controlled to supply a gaseous temperature control medium, and the gaseous temperature control medium is stored in the tank 30. That is, the temperature control medium is supplied from the supply mechanism 50 to the tank 30 without being exposed to the atmosphere. Thereafter, the temperature control medium is cooled and liquefied by the cooling mechanism 31. An airtightness test of the pipes 37 and 38 and the temperature control unit 11 can be performed by filling the inside of the pipes 37 and 38 and the inside of the temperature control unit 11 with a purge gas by setting the valve 57 to the open state from the open/close state of each valve in FIG. 2 and measuring the pressure by the pressure gauge 43. In addition, the airtightness test can be performed, for example, at the time of start-up of the apparatus after part replacement on the side of the plasma processing chamber 10 (temperature control unit 11).

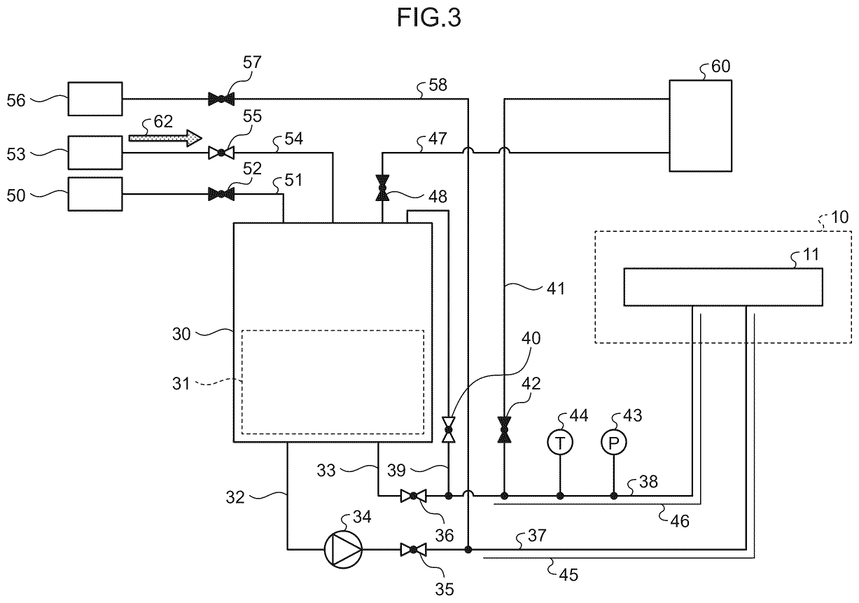

FIG. 3 is a diagram illustrating an example of a state during operation of the temperature control system. As illustrated in FIG. 3, during operation of the temperature control system 1, the valves 42, 48, 52, and 57 are controlled to be closed and the valves 35, 36, 40, and 55 are controlled to be open. As indicated by an arrow 62, the pressing mechanism 53 is controlled to supply a pressing gas, and the pressed temperature control medium is circulated by the pump 34 through the paths of the pipes 32 and 37, the temperature control unit 11, and the pipes 38 and 33. The temperature control medium vaporized during circulation is returned from the pipe 39 to the upper portion of the tank 30. The temperature control medium is pressurized by being pressed by the pressing mechanism 53, and dry-out in the temperature control unit 11 can be alleviated. In addition, when the temperature control medium is pressed, pressing is added to lift of the pump 34 (by suppressing the pressure loss), and thus the load on the pump 34 can be reduced. Furthermore, since the flow rate of the circulating temperature control medium increases, the cooling performance can be improved.

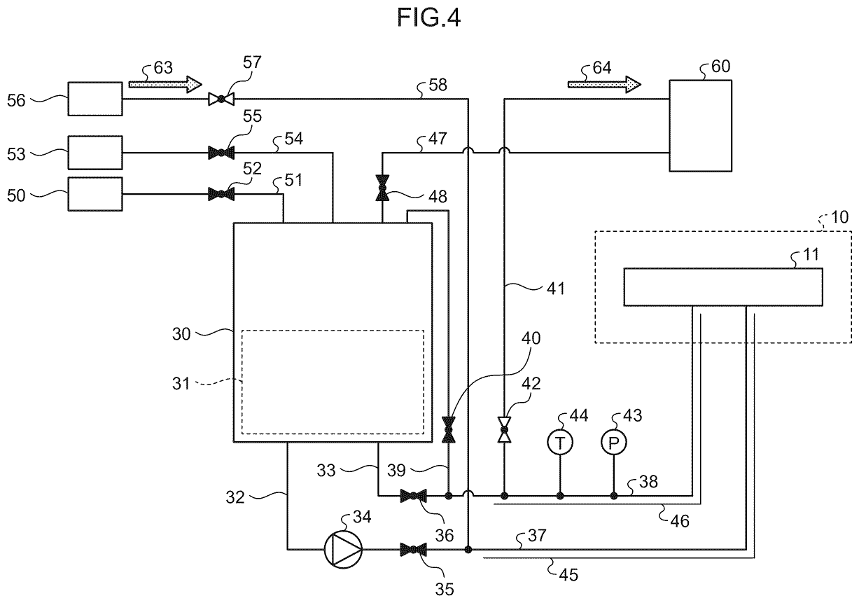

FIG. 4 is a diagram illustrating an example of a state in which the temperature control medium in pipes on the side of the temperature control unit is exhausted. As illustrated in FIG. 4, at the time of exhausting the temperature control medium remaining in the pipes 37 and 38 and the temperature control unit 11, the valves 35, 36, 40, 48, 52, and 55 are controlled to be closed and the valves 42 and 57 are controlled to be open. As indicated by an arrow 63, the purge mechanism 56 is controlled to supply a purge gas into the temperature control unit 11, the detoxification mechanism 60 is controlled to vacuum the pipe 41, and thus the insides of the pipes 37 and 38 and the temperature control unit 11 are purged and exhausted. The temperature of the pipes 37 and 38 is increased by the heaters 45 and 46. That is, the temperature control medium is exhausted to the detoxification mechanism 60 without being exposed to the atmosphere. The purge mechanism 56 and the detoxification mechanism 60 may perform cycle purge. After completion of the cycle purge, part replacement on the side of the plasma processing chamber 10 (temperature control unit 11) can be performed. The pipes 37 and 38 may include a connection part separable from the side of the plasma processing chamber 10. When the tank 30 and the cooling mechanism 31 are maintained, the tank 30 can be purged using the pressing gas of the pressing mechanism 53 by closing the valves 35, 36, 40, 42, 52, and 57 and opening the valves 48 and 55. In this case, the detoxification mechanism 60 is controlled to vacuum the pipe 47.

### Pressing of Temperature Control Medium

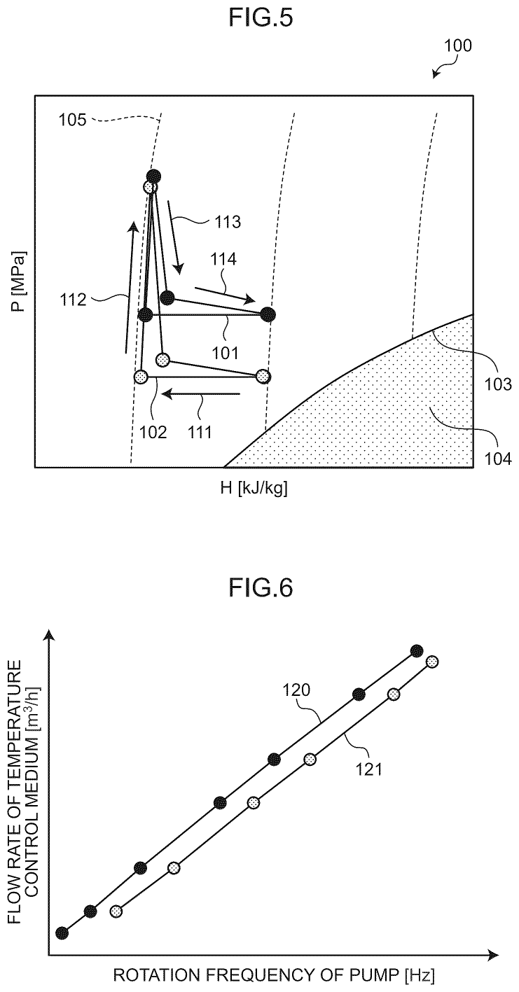

Next, P-H characteristics and change in a flow rate when a liquid temperature control medium is pressed will be described with reference to FIG. 5 and FIG. 6. FIG. 5 and FIG. 6 indicate a case in which C₃F₈ is used as a temperature control medium and nitrogen gas is used as a pressing gas. FIG. 5 is a graph indicating an example of P-H characteristics of the temperature control medium. As illustrated in FIG. 5, a P-H diagram 100 indicates P-H characteristics of the temperature control medium in the temperature control system 1. In the P-H diagram 100, the vertical axis represents the pressure P [MPa], and the horizontal axis represents the specific enthalpy H [kJ/kg]. A cycle 101 is a cycle in the case of pressing with nitrogen gas. On the other hand, a cycle 102 is a cycle in a case where there is no pressing with the nitrogen gas. A lower region 104 to the right of the saturated liquid line 103 in the P-H diagram 100 is a gas-liquid mixing (dry-out) region. The temperature of the temperature control medium in the cycles 101 and 102 is represented by an isotherm 105. Each of the cycles 101 and 102 has a cooling process 111, a pressurization process 112, a heat loading process 113, and a return process 114. In the cycle 101, since the cooling process 111 and the return process 114 are farther from the saturated liquid line 103 than the cycle 102, it can be seen that the margin for dry-out increases in the case of pressing with nitrogen gas.

FIG. 6 is a graph illustrating an example of change in a flow rate due to pressing of the temperature control medium. In FIG. 6, the vertical axis represents the flow rate [m³/h] of the temperature control medium, and the horizontal axis represents the rotation frequency [Hz] of the pump 34. A graph 120 illustrated in FIG. 6 indicates the relationship between the flow rate of the temperature control medium and the rotation frequency of the pump 34 in a case where there is pressing with the nitrogen gas. In addition, a graph 121 indicates the relationship between the flow rate of the temperature control medium and the rotation frequency of the pump 34 in a case where there is no pressing with the nitrogen gas. When the graphs 120 and 121 are compared, it can be seen that the flow rate of the temperature control medium increases even when the rotation frequency of the pump 34 is the same in the case where there is pressing with the nitrogen gas.

### Method of Controlling Temperature Control System

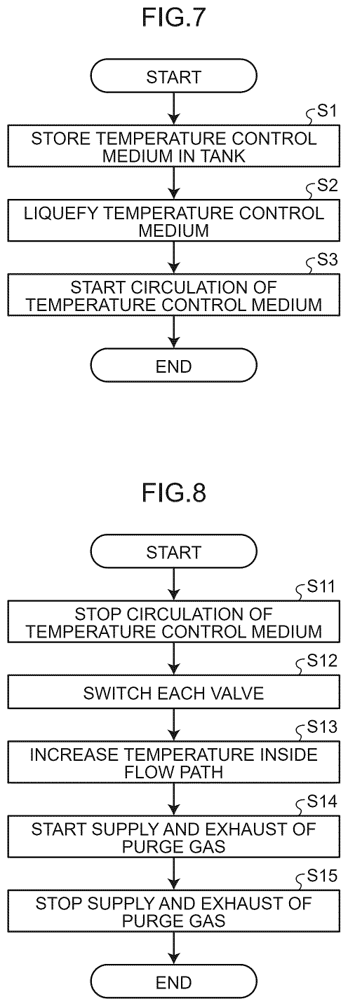

Next, a method of controlling the temperature control system in the present embodiment will be described. FIG. 7 is a flowchart illustrating an example of a method of controlling the temperature control system at the time of storage and circulation in the present embodiment.

At the start of storage and circulation of the temperature control medium, the control unit 3 controls the valves 35, 36, 40, 42, 48, 55, and 57 to be closed and controls the valve 52 to be opened. The control unit 3 controls the supply mechanism 50 to supply the gaseous temperature control medium at normal temperature and normal pressure to the tank 30 to store the gaseous temperature control medium (step S1). That is, step S1 is an example of a process of storing the gaseous temperature control medium in the tank 30 at normal temperature and normal pressure. The control unit 3 controls the cooling mechanism 31 to liquefy the temperature control medium stored in the tank 30 (step S2). That is, step S2 is an example of a process of liquefying the temperature control medium stored in the tank 30.

The control unit 3 controls the valve 52 to be closed and controls the valves 35, 36, 40, and 55 to be opened. The control unit 3 controls the pressing mechanism 53 to start supplying a pressing gas to the tank 30. The control unit 3 controls the pump 34 to start circulation of the pressed temperature control medium through the paths of the pipes 32 and 37, the temperature control unit 11, and the pipes 38 and 33 (step S3). That is, the control unit 3 controls each unit to circulate the liquefied temperature control medium to the temperature control unit 11 that cools the members while pressing the liquefied temperature control medium. In other words, step S3 is an example of a process of circulating the liquefied temperature control medium to the temperature control unit 11 that cools the members while pressing the liquefied temperature control medium. As a result, the temperature control system 1 can suppress release of the temperature control medium to the atmosphere by supplying the temperature control medium in an airtight state. That is, since the temperature control system 1 can expand the usable temperature range of the temperature control medium, the temperature control system 1 can be used in a low temperature region. In addition, the temperature control system 1 can expand the margin for dry-out and can increase the flow rate of the temperature control medium.

FIG. 8 is a flowchart illustrating an example of a method of controlling the temperature control system at the time of exhaust in the present embodiment.

At the time of exhausting the temperature control medium, the control unit 3 controls the pressing mechanism 53 to stop supply of the pressing gas to the tank 30. The control unit 3 controls the pump 34 to stop circulation of the temperature control medium (step S11). That is, step S11 is an example of a process of stopping circulation of the temperature control medium to the temperature control unit 11. The control unit 3 controls the valves 35, 36, 40, 48, 52, and 55 to be closed, and controls the valves 42 and 57 to be opened. That is, the control unit 3 switches each valve to exhaust the temperature control medium (step S12). In other words, step S12 is an example of a process of closing the first valve (valve 35) provided in the outflow flow path on the side where the temperature control medium flows out from the tank 30 to the temperature control unit 11 and the second valve (valve 36) provided in the inflow flow path on the side where the temperature control medium flows in from the temperature control unit 11 to the tank 30. The control unit 3 controls the heaters 45 and 46 to heat the pipes 37 and 38 and increase the temperature inside the flow paths of the pipe 37, the temperature control unit 11, and the pipe 38 (step S13). That is, step S13 is an example of a process of increasing the temperature inside the flow paths by the heater provided in at least one of the outflow flow path and the inflow flow path. At this time, the control unit 3 may perform control to increase the temperature inside the flow paths of the pipe 37, the temperature control unit 11, and the pipe 38 to a temperature equal to or higher than the boiling point of the temperature control medium. In addition, the control unit 3 opens the third valve (valve 40) provided in a flow path (pipe 39) branched from the inflow flow path (pipe 38) and connected to the upper portion of the tank 30, and performs control to return the vaporized temperature control medium to the tank 30.

The control unit 3 controls the purge mechanism 56 and the detoxification mechanism 60 to start supply and exhaust of a purge gas to and from the inside of the flow paths of the pipe 37, the temperature control unit 11, and the pipe 38 (step S14). That is, step S14 is an example of a process of supplying the purge gas from the purge mechanism 56 connected to the side of the temperature control unit 11 rather than the first valve of the outflow flow path to the outflow flow path, the temperature control unit 11, and the inflow flow path, and exhausting the purge gas to the exhaust flow path connected to the side of the temperature control unit rather than the second valve of the inflow flow path. The control unit 3 detects that the temperature control medium is exhausted from the inside of the pipe 38 on the basis of the measurement results input from the pressure gauge 43 and the thermometer 44. For example, the control unit 3 detects that the temperature control medium is exhausted from the pipe 38 (inflow flow path) on the basis of the temperature measured by the thermometer 44 being equal to or higher than the boiling point of the temperature control medium and the pressure measured by the pressure gauge 43 being equal to or lower than the vapor pressure at the measured temperature. That is, since the pipe 38 is on the downstream side of the flow path at the time of exhaust, it is possible to detect that the temperature control medium is exhausted from the inside of the flow path of the pipe 37, the temperature control unit 11, and the pipe 38 from the measurement results of the pressure gauge 43 and the thermometer 44 provided in the pipe 38. When the control unit 3 detects that the temperature control medium is exhausted from the inside of the pipe 38, the control unit 3 controls the purge mechanism 56 and the detoxification mechanism 60 to stop supply and exhaust of the purge gas to and from the inside of the flow path of the pipe 37, the temperature control unit 11, and the pipe 38 (step S15). That is, step S15 is an example of stopping the exhaust when it is detected that the temperature control medium is exhausted from the inside of the inflow flow path on the basis of a value measured by at least one of the pressure gauge 43 and the thermometer 44 provided in the inflow flow path. In an implementation, the control unit 3 controls the purge mechanism 56 and the detoxification mechanism 60 such that the inside of the flow path of the pipe 37, the temperature control unit 11, and the pipe 38 becomes normal pressure (e.g., atmospheric pressure) on the basis of the measurement result of the pressure gauge 43 when the exhaust is stopped. The control unit 3 performs control to close the valves 42 and 57. As a result, the temperature control system 1 can exhaust the temperature control medium to the detoxification mechanism 60 without exposing the temperature control medium to the atmosphere. In addition, since the temperature control system 1 does not expose the temperature control medium to the atmosphere, the number of types of usable temperature control medium can be increased.

As described above, according to the present embodiment, the temperature control system 1 is the temperature control system 1 that cools the members in the plasma processing chamber 10, and includes the tank 30, the cooling mechanism 31, the outflow flow path (the pipes 32 and 37), the inflow flow path (the pipes 33 and 38), and the pump 34. The tank 30 is configured to store a gaseous temperature control medium at normal temperature and normal pressure. The cooling mechanism 31 is configured to liquefy the temperature control medium stored in the tank 30. The outflow flow path is connected to the outflow port of the tank 30 and is configured such that the temperature control medium flows out to the temperature control unit 11 that cools the member by heat exchange using the temperature control medium. The inflow flow path is connected to the inflow port of the tank 30 and is configured such that the temperature control medium after heat exchange flows in from the temperature control unit 11. The pump 34 is provided in the outflow flow path and is configured to send the temperature control medium stored in the tank 30. As a result, the release of the temperature control medium to the atmosphere can be suppressed, and the usable temperature range of the temperature control medium can be expanded. That is, the temperature control system 1 can be used in a low temperature region.

According to the present embodiment, the temperature control system 1 further includes the supply mechanism 50 connected to the tank 30 and configured to supply a gaseous temperature control medium. As a result, the temperature control medium can be supplied to the tank 30 without being exposed to the atmosphere.

According to the present embodiment, the temperature control medium contains at least one of C₃F₈ and C₃H₂F₄. As a result, the temperature control system 1 can be used in a low temperature region.

Further, according to the present embodiment, the pressing mechanism 53 configured to press a liquid temperature control medium stored in the tank 30 is further provided. As a result, the margin for dry-out can be expanded, and the flow rate of the temperature control medium can be increased.

According to the present embodiment, the pressing mechanism 53 supplies a pressing gas into the tank 30 to press the temperature control medium. As a result, the margin for dry-out can be expanded, and the flow rate of the temperature control medium can be increased.

According to the present embodiment, the pressing gas is a gas having a boiling point lower than that of the temperature control medium. As a result, the temperature control medium can be pressed by the gas even in a low temperature region where the temperature control medium is liquefied.

According to the present embodiment, the pressing mechanism 53 presses the temperature control medium using a piston. As a result, the temperature control medium can be pressed even when the pressing gas cannot be prepared from the factory equipment (application force) in which the temperature control system 1 is installed.

Further, according to the present embodiment, the pressing mechanism 53 presses the temperature control medium to a vapor pressure of the temperature control medium or more. As a result, the margin for dry-out can be expanded, and the flow rate of the temperature control medium can be increased.

According to the present embodiment, heaters (heaters 45 and 46) are provided in at least one of the outflow flow path and the inflow flow path. As a result, the temperature control medium can be vaporized in the pipes 37 and 38 and the temperature control unit 11.

According to the present embodiment, at least one of the pressure gauge 43 and the thermometer 44 is provided in the inflow flow path. As a result, it is possible to detect that the temperature control medium is exhausted from the pipes 37 and 38 and the temperature control unit 11.

Further, according to the present embodiment, an exhaust flow path (pipe 41) connected to the tank 30 and the inflow flow path and configured to exhaust the temperature control medium is further provided. As a result, the temperature control medium can be exhausted to the detoxification mechanism 60 without being exposed to the atmosphere.

According to the present embodiment, the cooling mechanism 31 is provided in the tank 30 or in the inflow flow path. As a result, the temperature control medium can be liquefied.

Furthermore, according to the present embodiment, the purge mechanism 56 connected to the outflow flow path and configured to be able to supply a purge gas into the temperature control unit 11 is further included. As a result, the inside of the pipes 37 and 38 and the temperature control unit 11 can be purged.

Further, according to the present embodiment, the method of controlling the temperature control system 1 is a method of controlling the temperature control system 1 for cooling members in the plasma processing chamber 10, and includes a process of storing a gaseous temperature control medium in the tank 30 at normal temperature and normal pressure, a process of liquefying the temperature control medium stored in the tank 30, and a process of circulating the liquefied temperature control medium to the temperature control unit 11 for cooling the members while pressing the liquefied temperature control medium. As a result, the release of the temperature control medium to the atmosphere can be suppressed, and the usable temperature range of the temperature control medium can be expanded. That is, the temperature control system 1 can be used in a low temperature region.

According to the present embodiment, the method of controlling the temperature control system 1 includes a process of stopping circulation of the temperature control medium to the temperature control unit 11, a process of closing the first valve (valve 35) provided in the outflow flow path (pipes 32 and 37) on the side where the temperature control medium flows out from the tank 30 to the temperature control unit 11 and the second valve (valve 36) provided in the inflow flow path (pipes 33 and 38) on the side where the temperature control medium flows in from the temperature control unit 11 to the tank 30, and a process of supplying a purge gas from the purge mechanism 56 connected to the side of the temperature control unit 11 rather than the first valve of the outflow flow path to the outflow flow path, the temperature control unit 11, and the inflow flow path, and exhausting the purge gas to an exhaust flow path (pipe 41) connected to the side of the temperature control unit rather than the second valve of the inflow flow path. As a result, the temperature control medium can be exhausted to the detoxification mechanism 60 without being exposed to the atmosphere.

In addition, according to the present embodiment, before the exhausting process, a process of increasing the temperature inside the flow path by heaters (heaters 45 and 46) provided in at least one of the outflow flow path and the inflow flow path is further included. As a result, the temperature control medium can be vaporized in the pipes 37 and 38 and the temperature control unit 11.

According to the present embodiment, in the temperature increasing process, the temperature inside the flow path is increased to a temperature equal to or higher than the boiling point of the temperature control medium. As a result, the temperature control medium can be further vaporized in the pipes 37 and 38 and the temperature control unit 11.

According to the present embodiment, in the temperature increasing process, the third valve (valve 40) provided in the flow path (pipe 39) branched from the inflow flow path and connected to the upper portion of the tank 30 is opened, and the vaporized temperature control medium is returned to the tank 30. As a result, the amount of the temperature control medium that can be collected in the tank 30 can be increased.

According to the present embodiment, in the exhaust process, when it is detected that the temperature control medium is exhausted from the inside of the inflow flow path on the basis of a value measured by at least one of the pressure gauge 43 and the thermometer 44 provided in the inflow flow path, exhaust is stopped. As a result, maintenance such as part replacement can be performed on the side of the plasma processing chamber 10.

Further, according to the present embodiment, in the exhausting process, it is detected that the temperature control medium is exhausted from the inside of the inflow flow path on the basis of the fact that the temperature measured by the thermometer 44 is equal to or higher than the boiling point of the temperature control medium and the fact that the pressure measured by the pressure gauge 43 is equal to or lower than the vapor pressure at the measured temperature. As a result, completion of exhaust of the temperature control medium from the inside of the inflow flow path can be detected more accurately.

The embodiments disclosed herein are to be considered in all respects as illustrative and not restrictive. The above embodiments may be omitted, replaced, or modified in various forms without departing from the scope and spirit of the appended claims.

Although the case where the temperature control system 1 is connected to the plasma processing apparatus including the plasma processing chamber 10 and cools the members in the plasma processing chamber 10 has been described in the above embodiment, the embodiments are not limited thereto. For example, a member to be cooled may be applied to members included in a modifying device that performs an annealing treatment or the like, a cleaning device that cleans a substrate, or the like.

Note that the present disclosure can also have the following configurations.
(1)

A temperature control system for cooling members in a plasma processing chamber, the temperature control system comprising:
a tank configured to store a gaseous temperature control medium at normal temperature and normal pressure;
a cooling mechanism configured to liquefy the temperature control medium stored in the tank;
an outflow flow path connected to an outflow port of the tank and configured to allow the temperature control medium to flow out to a temperature control unit that cools the members by heat exchange using the temperature control medium;
an inflow flow path connected to an inflow port of the tank and configured such that the temperature control medium after heat exchange flows in from the temperature control unit; and
a pump provided in the outflow flow path and configured to send the temperature control medium stored in the tank.
(2)

The temperature control system according to (1), further comprising
a supply mechanism connected to the tank and configured to supply the gaseous temperature control medium.
(3)

The temperature control system according to (1) or (2), wherein
the temperature control medium includes at least one of C₃F₈ and C₃H₂F₄.
(4)

The temperature control system according to any one of (1) to (3), further comprising
a pressing mechanism configured to press the liquid temperature control medium stored in the tank.
(5)

The temperature control system according to (4), wherein
the pressing mechanism supplies a pressing gas into the tank to press the temperature control medium.
(6)

The temperature control system according to (5), wherein
the pressing gas is a gas having a boiling point lower than a boiling point of the temperature control medium.
(7)

The temperature control system according to (4), wherein
the pressing mechanism presses the temperature control medium by a piston.
(8)

The temperature control system according to any one of (4) to (7), wherein
the pressing mechanism presses the temperature control medium to a vapor pressure of the temperature control medium or more.
(9)

The temperature control system according to any one of (1) to (8), wherein
a heater is provided in at least one of the outflow flow path and the inflow flow path.
(10)

The temperature control system according to any one of (1) to (9), wherein
at least one of a pressure gauge and a thermometer is provided in the inflow flow path.
(11)

The temperature control system according to any one of (1) to (10), further comprising
an exhaust flow path connected to the tank and the inflow flow path and configured to exhaust the temperature control medium.
(12)

The temperature control system according to any one of (1) to (11), wherein
the cooling mechanism is provided in the tank or the inflow flow path.
(13)

The temperature control system according to any one of (1) to (12), further comprising
a purge mechanism connected to the outflow flow path and configured to be able to supply a purge gas into the temperature control unit.
(14)

A method of controlling a temperature control system for cooling members in a plasma processing chamber, the method comprising:
a process of storing a gaseous temperature control medium in a tank at normal temperature and normal pressure;
a process of liquefying the temperature control medium stored in the tank; and
a process of circulating the liquefied temperature control medium to a temperature control unit that cools the members while pressing the liquefied temperature control medium.
(15)

The method of controlling a temperature control system according to (14), further comprising:
a process of stopping circulation of the temperature control medium to the temperature control unit;
a process of closing a first valve provided in an outflow flow path on a side where the temperature control medium flows out from the tank to the temperature control unit and a second valve provided in an inflow flow path on a side where the temperature control medium flows in from the temperature control unit to the tank; and
a process of supplying a purge gas from a purge mechanism connected to the side of the temperature control unit rather than the first valve of the outflow flow path to the outflow flow path, the temperature control unit, and the inflow flow path, and exhausting the purge gas to an exhaust flow path connected closer to the side of the temperature control unit rather than the second valve of the inflow flow path.
(16)

The method of controlling a temperature control system according to (15), further comprising
a process of increasing a temperature inside the flow path by a heater provided in at least one of the outflow flow path and the inflow flow path before the exhausting process.
(17)

The method of controlling a temperature control system according to (16), wherein
the temperature increasing process increases the temperature inside the flow path to a temperature equal to or higher than a boiling point of the temperature control medium.
(18)

The method of controlling a temperature control system according to (17), wherein
the temperature increasing process opens a third valve provided in a flow path branched from the inflow flow path and connected to an upper portion of the tank to return the vaporized temperature control medium to the tank.
(19)

The method of controlling a temperature control system according to any one of (15) to (18), wherein
the exhausting process stops the exhaust when it is detected that the temperature control medium is exhausted from the inside of the inflow flow path on the basis of a value measured by at least one of a pressure gauge and a thermometer provided in the inflow flow path.
(20)

The method for controlling a temperature control system according to (19), wherein
the exhausting process detects that the temperature control medium is exhausted from the inside of the inflow flow path on the basis of a fact that a temperature measured by the thermometer is equal to or higher than a boiling point of the temperature control medium and a fact that a pressure measured by the pressure gauge is equal to or lower than a vapor pressure at the measured temperature.

According to the present disclosure, it can be used in a low temperature region.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated.

What is claimed is

1. A temperature control system for cooling structures in a plasma processing chamber, the temperature control system comprising:
a tank that stores a gaseous temperature control medium at normal temperature and normal pressure;
a cooler that liquefies the temperature control medium stored in the tank;
an outflow flow path connected to an outflow port of the tank, the outflow flow path forming a flow path through which the temperature control medium flows out to a temperature control structure that cools the structures by heat exchange with the temperature control medium;
an inflow flow path connected to an inflow port of the tank and forming a flow path through which the temperature control medium flows in from the temperature control structure after heat exchange;
a pump in the outflow flow path and that moves the temperature control medium stored in the tank; and
a pressing structure that presses the liquid temperature control medium stored in the tank.

2. The temperature control system according to claim 1, further comprising a supply connected to the tank, the supply supplying the gaseous temperature control medium.

3. The temperature control system according to claim 1, wherein the temperature control medium includes at least one of C₃F₈ and C₃H₂F₄.

4. The temperature control system according to claim 1, wherein the pressing structure supplies a pressing gas into the tank that presses the temperature control medium.

5. The temperature control system according to claim 4, wherein the pressing gas is a gas having a boiling point that is lower than a boiling point of the temperature control medium.

6. The temperature control system according to claim 1, wherein the pressing structure presses the temperature control medium with a piston.

7. The temperature control system according to claim 1, wherein the pressing structure presses the temperature control medium to a pressure that is equal to a vapor pressure of the temperature control medium or higher.

8. The temperature control system according to claim 1, further comprising a heater on at least one of the outflow flow path and the inflow flow path.

9. The temperature control system according to claim 1, further comprising at least one of a pressure gauge and a thermometer in the inflow flow path.

10. The temperature control system according to claim 1, further comprising an exhaust flow path connected to the tank and the inflow flow path, the exhaust flow path exhausting the temperature control medium.

11. The temperature control system according to claim 1, wherein the cooler is in the tank or the inflow flow path.

12. The temperature control system according to claim 1, further comprising a purge structure connected to the outflow flow path, the purge structure supplying a purge gas into the temperature control unit.

13. A method of controlling a temperature control system for cooling structures in a plasma processing chamber, the method comprising:
storing a gaseous temperature control medium in a tank at normal temperature and normal pressure;
liquefying the temperature control medium stored in the tank;
circulating the liquefied temperature control medium to a temperature control structure that cools the structures while pressing the liquefied temperature control medium;
stopping circulation of the temperature control medium to the temperature control structure;
closing a first valve in an outflow flow path on a side where the temperature control medium flows out from the tank to the temperature control structure and closing a second valve in an inflow flow path on a side where the temperature control medium flows in from the temperature control structure to the tank; and
supplying a purge gas from a purge structure including a purge pipe that is connected to the outflow flow path such that the connection between the purge pipe and the outflow flow path is closer to the side of the temperature control structure than the first valve of the outflow flow path is to the side of the temperature control structure, and exhausting the purge gas to an exhaust flow path that is connected to the inflow flow path such that the connection between the exhaust flow path is closer to the side of the temperature control structure than the second valve of the inflow flow path is to the side of the temperature control structure.

14. The method of controlling a temperature control system according to claim 13, further comprising increasing a temperature inside at least one of the outflow flow path and the inflow flow path with a heater included in the at least one of the outflow flow path and the inflow flow path, before the exhausting.

15. The method of controlling a temperature control system according to claim 14, wherein increasing the temperature increases the temperature inside the at least one of the outflow flow path and the inflow flow path to a temperature that is equal to or higher than a boiling point of the temperature control medium.

16. The method of controlling a temperature control system according to claim 15, wherein increasing the temperature further includes opening a gaseous return valve included in a gaseous return pipe that is connected to and branched from the inflow flow path and connected to an upper portion of the tank to return the vaporized temperature control medium to the tank.

17. The method of controlling a temperature control system according to claim 13, further comprising:
detecting that the temperature control medium is exhausted from inside of the inflow flow path; and
stopping the exhausting.

18. The method for controlling a temperature control system according to claim 17, wherein, in the detecting that the temperature control medium is exhausted from the inside of the inflow flow path:
a temperature measured by a thermometer in the inflow flow path is equal to or higher than a boiling point of the temperature control medium, or
a pressure measured by a pressure gauge in the inflow flow path is equal to or lower than a vapor pressure at the measured temperature.

19. The method of controlling a temperature control system according to claim 13, wherein the temperature control medium includes at least one of C₃F₈ and C₃H₂F₄.

20. The method of controlling a temperature control system according to claim 13, wherein circulating the liquefied temperature control medium includes moving the liquefied temperature control medium with a pump.
